(19) United States
(12) Patent Application Publication
(10) Pub. No.: US 2026/0135338 A1
(43) Pub. Date: May 14, 2026

(54) SOCKET MODULE AND SOCKET DEVICE COMPRISING THE SAME

(71) Applicant: LITE-ON TECHNOLOGY CORPORATION, Taipei (TW)

(72) Inventors: Ming-Feng TANG, Taipei (TW); Chi-Tai CHEN, Taipei (TW)

(21) Appl. No.: 19/270,519

(22) Filed: Jul. 16, 2025

Related U.S. Application Data
(60) Provisional application No. 63/719,673, filed on Nov. 13, 2024.

(30) Foreign Application Priority Data
Jun. 25, 2025 (CN) 202510859047.1

(51) Int. Cl. H01R 24/78; H01R 13/512; H01R 13/58; H01R 13/652; H01R 13/6583; H01R 105/00; H05K 7/20

(52) U.S. Cl. CPC H01R 24/78; H01R 13/512; H01R 13/5812; H01R 13/652; H01R 13/6583; H05K 7/20172; H01R 2105/00

(57) ABSTRACT

A socket module is provided. The socket module includes a cover member, a socket member, an elastic member, a first fastening member and a second fastening member. The socket member passes through the cover member, and the socket member includes a first pin. The first pin serves as a ground wire. The elastic member is engaged in the cover member, in electrical contact with the socket member, and is electrically connected to the first pin. The first fastening member and the second fastening member abut against and press the elastic member in different directions. The elastic member is secured within the cover member by the first fastening member and the second fastening member, and the elastic member is a closed structure.

This application claims the benefit of U.S. provisional application Ser. No. 63/719,673, filed Nov. 13, 2024, and People's Republic of China Application No. 202510859047.1, filed Jun. 25, 2025, the subject matters of which are incorporated herein by reference.

### BACKGROUND OF THE INVENTION

### Field of the Invention

The invention relates in general to a socket module and a socket device including the same, and more particularly to a socket module and a socket device including the same that can solve electromagnetic interference problems.

### Description of the Related Art

In the prior art, to solve the problems of electromagnetic compatibility (EMC) and electromagnetic interference (EMI) of socket devices, electronic methods or non-electronic methods are usually employed. Electronic methods include, for example, adding electronic circuits or electronic components to the socket device; non-electronic methods include, for example, adding conductive foam to the socket device.

However, regardless of whether current electronic methods or non-electronic methods are used, they require occupying a larger space inside the socket device. Therefore, there is still an urgent need to develop a technical means that can comply with the internal space limitations of the socket device and can improve the electromagnetic compatibility and electromagnetic interference problems of the socket device.

### SUMMARY OF THE INVENTION

The present invention is directed to improve the problems of electromagnetic compatibility and electromagnetic interference of the socket module, in particular by enhancing the grounding effect to solve the problems of electromagnetic compatibility and electromagnetic interference.

According to some embodiments, the present invention provides a socket module. The socket module includes a cover member, a socket member, an elastic member, a first fastening member, and a second fastening member. The socket member penetrates through the cover member, and the socket member includes a first pin, wherein the first pin serves as a ground wire. The elastic member is engaged in the cover member, is in electrical contact with the socket member, and is electrically connected to the first pin. The first fastening member and the second fastening member abut against and press the elastic member in different directions, and the elastic member is secured within the cover member by the first fastening member and the second fastening member, wherein the elastic member has a closed structure.

According to some embodiments, the present invention provides a socket device. The socket device includes a housing, a socket module, and a fan. The housing includes a first end and a second end opposite to each other along a long axis. The socket module is disposed at the first end. The fan is disposed between the first end and the second end.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a socket device according to a first embodiment of the present invention.

FIG. 2 is an exploded schematic diagram of the socket device according to the first embodiment of the present invention.

FIGS. 3A and 3B are schematic diagrams of a socket module according to the first embodiment of the present invention.

FIGS. 4A to 4D are schematic diagrams of an elastic member according to the first embodiment of the present invention from different perspectives.

FIG. 5 is a schematic diagram of a socket device according to a second embodiment and a third embodiment of the present invention.

FIG. 6 is an exploded schematic diagram of a socket device according to the second embodiment of the present invention.

FIG. 7 is an exploded schematic diagram of a socket device according to the third embodiment of the present invention.

FIGS. 8A and 8B are schematic diagrams of a socket module according to the second embodiment and the third embodiment of the present invention.

### DETAILED DESCRIPTION OF THE INVENTION

Hereinafter, various embodiments will be described in more detail with reference to the accompanying drawings. The descriptions and drawings are provided for illustrative purposes only and are not intended to be limiting. For clarity, some elements and/or symbols may be omitted in some drawings. In addition, elements in the drawings may not be drawn to actual scale. It is anticipated that elements and features from one embodiment can be advantageously incorporated into another embodiment without further redundant description.

In some applications, socket devices have the following three limitations:
(1) Space limitation: Due to design requirements, the internal space of the socket device is reduced, leaving no sufficient space to add electronic circuits, electronic components, or to use commercially available conductive foam or shrapnel.
(2) Assembly limitation: Even with reduced internal space, it is still necessary to consider mass production quality yield and existing factory process capabilities, ensuring that the manufacturing process of the socket device does not become difficult.
(3) Structural strength limitation: The socket device must meet structural strength testing requirements, so that components in the socket device do not fall off.

In view of these, the present invention provides a socket device that can comply with the above three limitations, and the formed socket device can improve electromagnetic compatibility and electromagnetic interference problems.

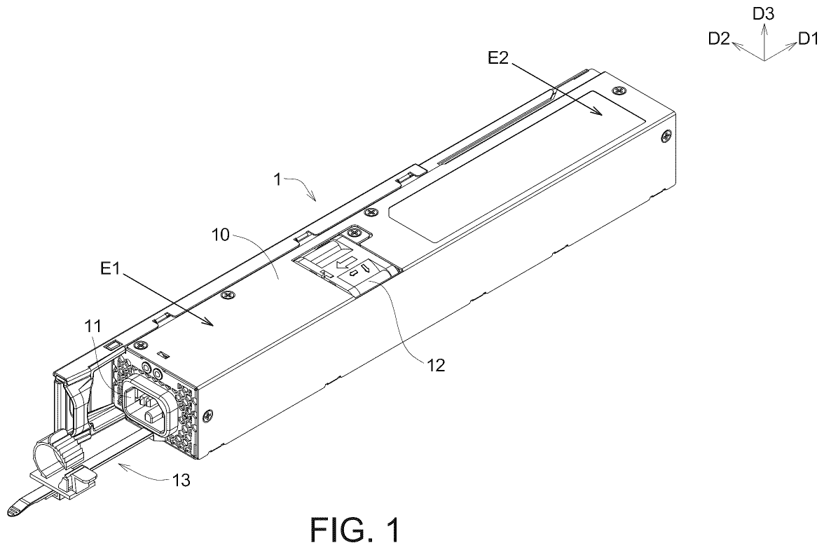

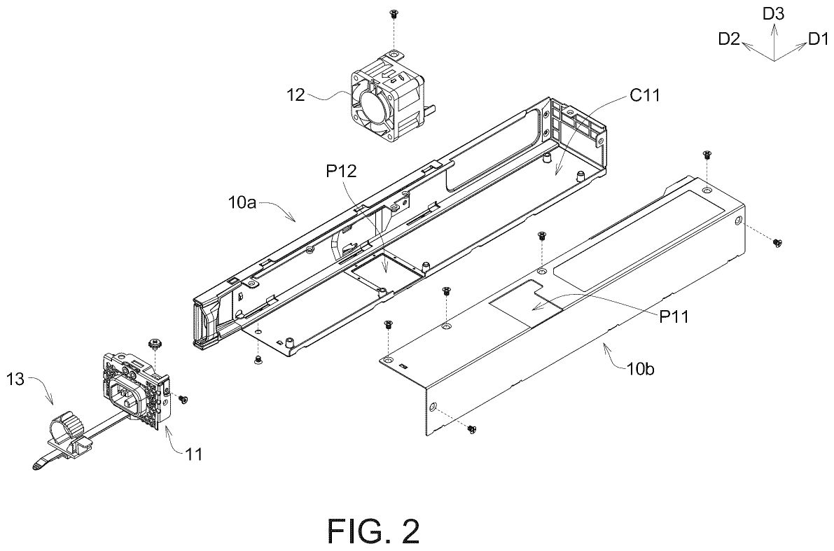

Please refer to FIGS. 1 and 2, the socket device 1 includes a housing 10, a socket module 11, a fan 12, and a fixing member 13. The housing 10 extends along a first direction D1. A length of the housing 10 in the first direction D1 is, for example, greater than a width of the housing 10 in a second direction D2, and greater than a height of the housing 10 in a third direction D3. The first direction D1, the second direction D2, and the third direction D3 are, for example, mutually perpendicular. The housing 10 may include a first end E1 and a second end E2 opposite to each other along a long axis. The extension direction of the long axis is parallel to the first direction D1. The socket module 11 is disposed at the first end E1 of the housing 10. The fan 12 is disposed in the housing 10 and located between the first end E1 and the second end E2. The fixing member 13 is connected to the socket module 11. The fixing member 13 can be used to fix wires, for example, to prevent wires connected to the socket module 11 from falling off.

The housing 10 may include a first housing member 10a and a second housing member 10b. The first housing member 10a and the second housing member 10b are assembled to form an accommodating space C11. The fan 12 is disposed within the accommodating space C11. The first housing member 10a and the second housing member 10b can respectively form a first opening P11 and a second opening P12 corresponding to the fan 12. The first opening P11 and the second opening P12 respectively expose a part of the fan 12.

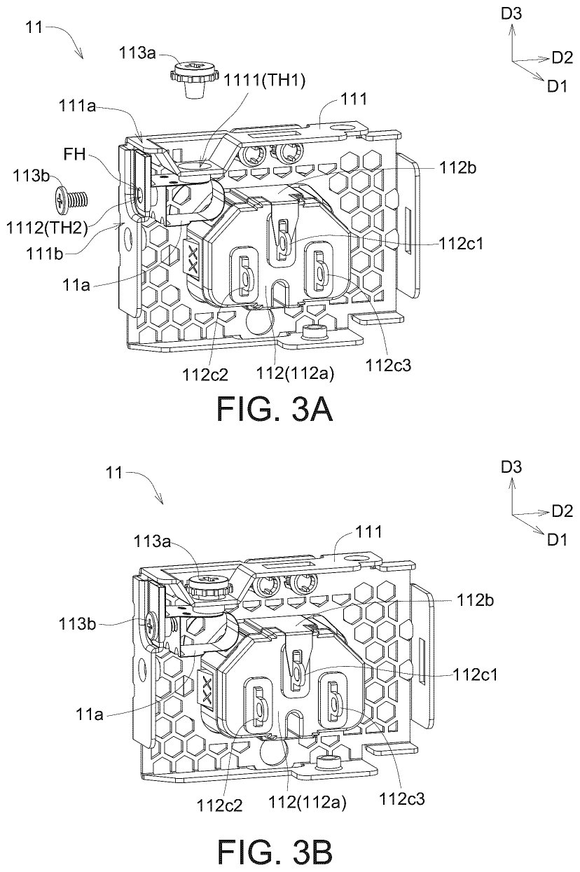

Please refer to FIGS. 3A and 3B, the socket module 11 includes a cover member 111, a socket member 112, an elastic member 11a, a first fastening member 113a, and a second fastening member 113b. The socket member 112 penetrates through the cover member 111, for example, being disposed in the central part of the cover member 111. The elastic member 11a is engaged in the cover member 111, and is in electrical contact with the socket member 112. The elastic member 11a is, for example, disposed in a corner on the inner side of the cover member 111, occupying minimal space. As shown in FIG. 3A, the cover member 111 includes a first recess 1111 and a second recess 1112. The first recess 1111 and the second recess 1112 are respectively located on two adjacent sides 111a, 111b of the cover member 111, and the elastic member 11a is disposed in the corner formed by the two sides 111a, 111b. The first recess 1111 and the second recess 1112 respectively have a first through hole TH1 and a second through hole TH2. The first through hole TH1 and the second through hole TH2 respectively expose a part of the elastic member 11a. The first fastening member 113a and the second fastening member 113b respectively correspond to the first through hole TH1 and the second through hole TH2. As shown in FIG. 3B, the first fastening member 113a and the second fastening member 113b abut against and press the elastic member 11a in different directions (e.g., directions parallel to the second direction D2 and the third direction D3), so that the elastic member 11a contacts, presses, and abuts against the socket member 112, and the elastic member 11a is secured within the cover member 111 by the first fastening member 113a and the second fastening member 113b. The socket member 112 includes a base 112a, a conductive ring 112b, a first pin 112c1, a second pin 112c2, and a third pin 112c3. The base 112a may include insulating material. The conductive ring 112b may include metal material. The first pin 112c1, the second pin 112c2, and the third pin 112c3 pass through the base 112a. The first pin 112c1 is, for example, a ground wire, the second pin 112c2 is, for example, a neutral wire, and the third pin 112c3 is, for example, a live wire. The conductive ring 112b surrounds the base 112a and is electrically connected to the first pin 112c1. The second pin 112c2 and the third pin 112c3 can be electrically connected to a circuit board (not shown) disposed in the accommodating space C11.

Specifically, the first fastening member 113a and/or the second fastening member 113b contacts and applies pressure to the elastic member 11a, causing the elastic member 11a to be compressed and deformed, and to adhere tightly to the socket member 112, for example, in tight electrical contact with the conductive ring 112b. Thereby, the elastic member 11a can be coupled to a ground wire through the first fastening member 113a and/or the second fastening member 113b. By means of the ground wire and the elastic member 11a, a reliable grounding effect for the socket member 112 can be provided, thereby solving the problems of electromagnetic compatibility (EMC) and electromagnetic interference (EMI) of the socket device.

In some embodiments, a wire (not shown) is electrically connected between the first fastening member 113a and the first pin 112c1. Compared to comparative examples where only a single wire (not shown) provides a ground path, in the present embodiment, in addition to the ground path of the wire (not shown), the elastic member 11a provides another ground path, and under the pressure of the first fastening member 113a and/or the second fastening member 113b, there is a sufficiently large contact area between the elastic member 11a and the conductive ring 112b, which reduces impedance, thus enhancing the reliability of the grounding effect.

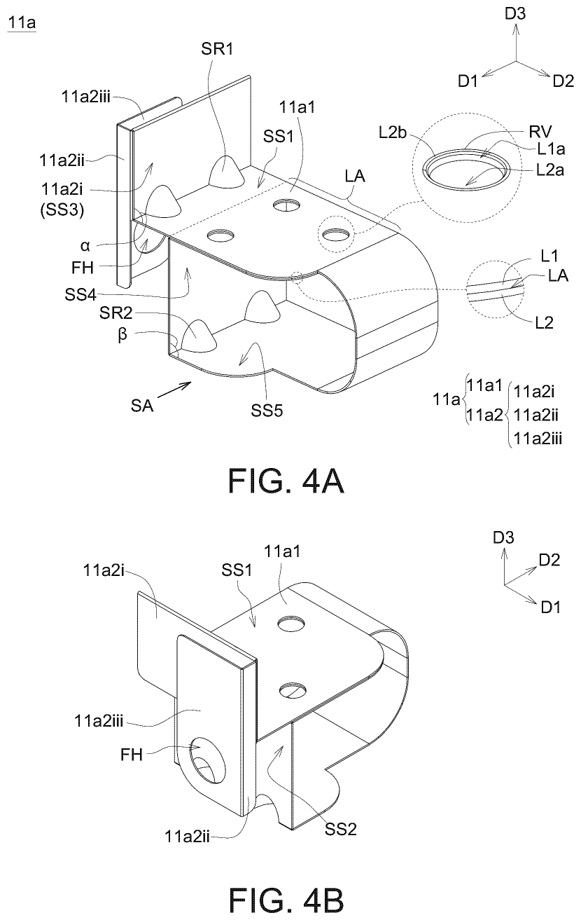

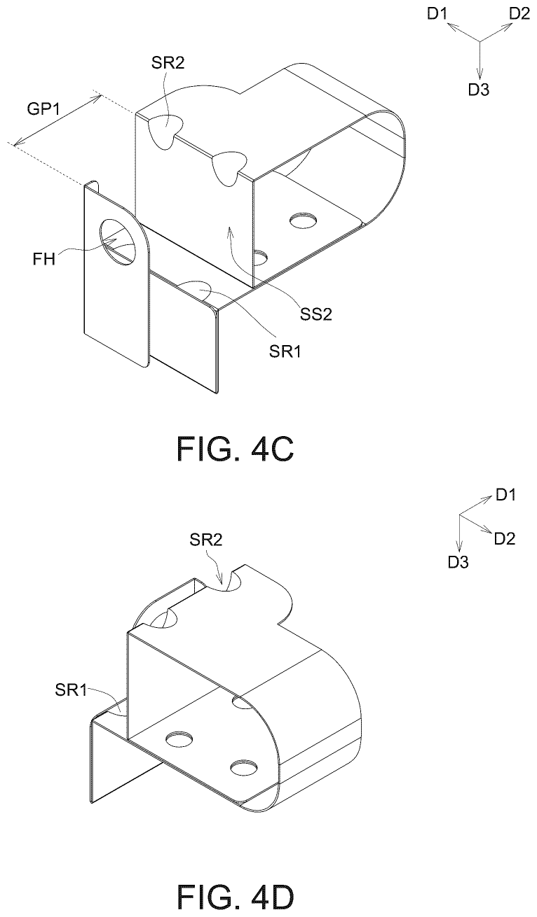

Please refer to FIGS. 4A to 4D, the elastic member 11a has a closed structure, and its material is metal, such as elastic steel, with a single layer thickness of, for example, 0.1 millimeters (mm), but the present invention is not limited thereto. The closed structure means that the elastic member 11a is annular, i.e., encircling to form a closed space in a side view, rather than an open space. Viewed from a side angle (e.g., the perspective of arrow SA in FIG. 4A), the boundary line of the elastic member 11a is continuous and without obvious breaks, forming a complete closed contour. Therefore, the elastic member 11a is not a C-shaped structure, U-shaped structure, or other open structures in the side view, but an arbitrarily shaped closed structure.

According to some embodiments, the elastic member 11a includes a body portion 11a1 and an extension portion 11a2, wherein the extension portion 11a2 is connected to the body portion 11a1. The body portion 11a1 has a closed structure. The entire elastic member 11a, including the body portion 11a1 and the extension portion 11a2, is an integrally formed structure. The extension portion 11a2 includes a first component 11a2i, a second component 11a2ii , and a third component 11a2iii, wherein the second component 11a2ii is connected between the first component 11a2i and the third component 11a2iii. The first component 11a2i is connected to the body portion 11a1. The second component 11a2ii and the third component 11a2iii partially protrude from the first component 11a2i, and the third component 11a2iii has a fixing hole FH, wherein the fixing hole FH corresponds to the part of the third component 11a2iii protruding from the first component 11a2i.

As shown in FIGS. 3A to 3B and FIGS. 4A to 4D, the second recess 1112 of the cover member 111 is clamped between the first component 11a2i, the second component 11a2ii, and the third component 11a2iii, and the fixing hole FH can correspond to the second through hole TH2. For example, the fixing hole FH overlaps the second through hole TH2 in the second direction D2. The first through hole TH1 exposes a part of the top surface SS1 (FIG. 4A) of the body portion 11a1. The second through hole TH2 exposes a part of the side surface SS2 of the body portion 11a1. There is a gap GP1 (FIG. 4C) between the third component 11a2iii and the side surface SS2 of the body portion 11a1. The first fastening member 113a passes through the first through hole TH1 to contact and press the top surface SS1, squeezing the elastic member 11a towards the socket member 112. After the second fastening member 113b passes through the fixing hole FH and the second through hole TH2 to fasten the elastic member 11a to the cover member 111, the gap GP1 decreases, and the second fastening member 113b contacts and presses the side surface SS2, squeezing the elastic member 11a towards the socket member 112. Therefore, by means of the first fastening member 113a and the second fastening member 113b, pressure can be applied to the elastic member 11a in different directions (e.g., pressure directions parallel to the third direction D3 and the second direction D2, respectively), thus allowing the elastic member 11a to be squeezed to make good electrical contact with the conductive ring 112b of the socket member 112.

In the present embodiment, the elastic member 11a is a closed structure formed by bending a single elastic sheet, so the two end regions of the body portion 11a1 of the elastic member 11a overlap each other to form an overlapping portion LA, which includes a double-layer structure formed by an upper layer L1 and a lower layer L2 of the body portion 11a. However, the present invention is not limited thereto. In other embodiments, the elastic member 11a can form a closed structure by automated processing techniques such as mold processing (e.g., stamping, hard tooling), non-mold processing (e.g., Computer Numerical Control (CNC), Numerical Control Turret Punch Press (NCT) processing, laser processing), or other methods.

As shown in FIG. 4A, the body portion 11a1 of the elastic member 11a further includes engaging portions RV. In the present embodiment, the engaging portions RV are, for example, disposed on the top surface SS1 of the body portion 11a1, and the number of engaging portions RV is 3. However, the arrangement and number of engaging portions RV are not limited thereto, as long as they can enable the elastic member 11a to form a stable closed structure. The upper layer L1 and the lower layer L2 are fixed to each other by the engaging portions RV. In the present embodiment, the engaging portions RV include a first engaging hole L1a, a second engaging hole L2a, and a fixing structure L2b adjacent to the second engaging hole L2a. The first engaging hole L1a is formed in the upper layer L1, and the second engaging hole L2a and the fixing structure L2b are formed in the lower layer L2, wherein the fixing structure L2b can protrude from the second engaging hole L2a. The first engaging hole L1a and the second engaging hole L2a overlap each other in the third direction D3. The fixing structure L2b passes through the first engaging hole L1a and folds outward, so that the fixing structure L2b extends over a portion of the upper layer L1. After the crimping process (applying pressure to the fixing structure L2b to fold it flat onto the upper layer L1), the folded area tightly clamps the upper layer L1 and the lower layer L2, and the upper layer L1 and the lower layer L2 can be securely engaged with each other through the engaging portions RV. In the enlarged view of FIG. 4A, the fixing structure L2b may have a roughly circular flat contour, but the present invention is not limited thereto, and the fixing structure L2b may have an irregular contour. According to some embodiments, the engaging portions RV include rivets or other fixing elements.

As shown in FIG. 4A, the elastic member 11a further includes a first angle α and a second angle β, and the predetermined angles of the first angle α and the second angle β are, for example, approximately 90 degrees, respectively. The first angle α is formed between the top surface SS1 and the inner side surface SS3 of the first component 11a2i adjacent to the top surface SS1. The second angle β is formed between the first internal surface SS4 and second internal surface SS5 of the body portion 11a1 adjacent to each other. The first internal surface SS4 and the second internal surface SS5 face the interior of the closed structure of the body portion 11a1. Before the elastic member 11a is deformed, the top surface SS1 is perpendicular to the inner side surface SS3, the first internal surface SS4 is perpendicular to the second internal surface SS5, the top surface SS1 is parallel to the second internal surface SS5, and the inner side surface SS3 is parallel to the first internal surface SS4.

The elastic member 11a may further include a first reinforcing rib SR1 and a second reinforcing rib SR2. The first reinforcing rib SR1 corresponds to the first angle α and is formed at the boundary edge between the body portion 11a1 and the first component 11a2i of the extension portion 11a2, i.e., between the top surface SS1 and the inner side surface SS3. The second reinforcing rib SR2 corresponds to the second angle β and is formed between the first internal surface SS4 and the second internal surface SS5. The first reinforcing rib SR1 can be formed by a part of the body portion 11a1 and a part of the first component 11a2i protruding in a direction away from the third component 11a2iii. The second reinforcing rib SR2 can be formed by the body portion 11a1 protruding in the direction away from the third component 11a2iii. Viewed from the perspective of FIG. 4A, the first reinforcing rib SR1 and the second reinforcing rib SR2 are protrusions. Viewed from the perspectives of FIGS. 4B to 4D, the first reinforcing rib SR1 and the second reinforcing rib SR2 are recesses. The arrangement of the first reinforcing rib SR1 and the second reinforcing rib SR2 is to maintain the predetermined angles (e.g., approximately 90 degrees) of the first angle α and the second angle β, to prevent the first angle α and the second angle β from changing too much when the elastic member 11a is deformed under pressure. In the present embodiment, the number of the first reinforcing ribs SR1 and the second reinforcing ribs SR2 is 2 respectively, but the present invention is not limited thereto. The number of the first reinforcing ribs SR1 and the number of the second reinforcing ribs SR2 can be 1 or greater than 2 respectively, and the number of the first reinforcing ribs SR1 and the number of the second reinforcing ribs SR2 can also be different from each other.

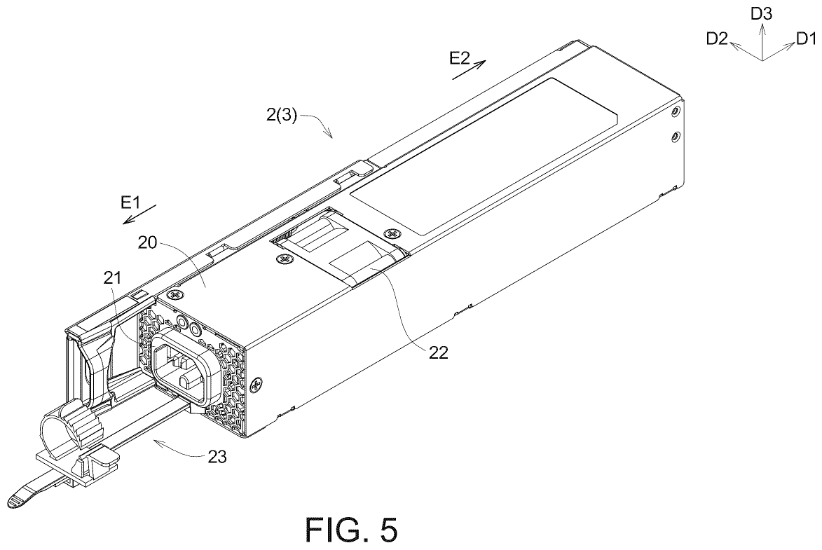

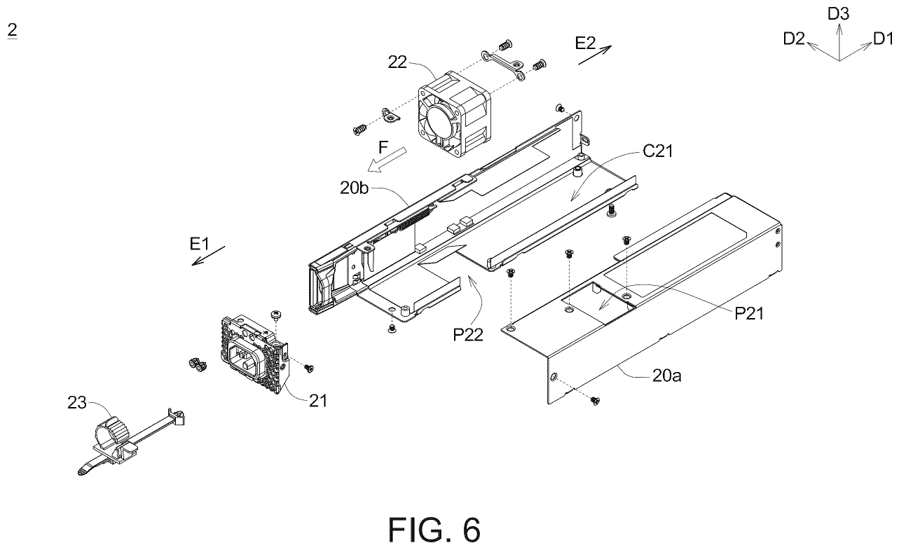

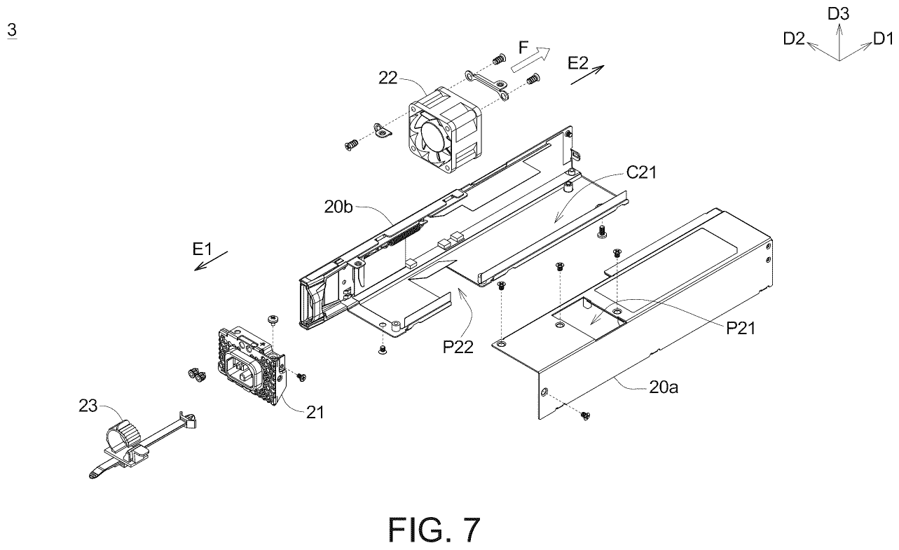

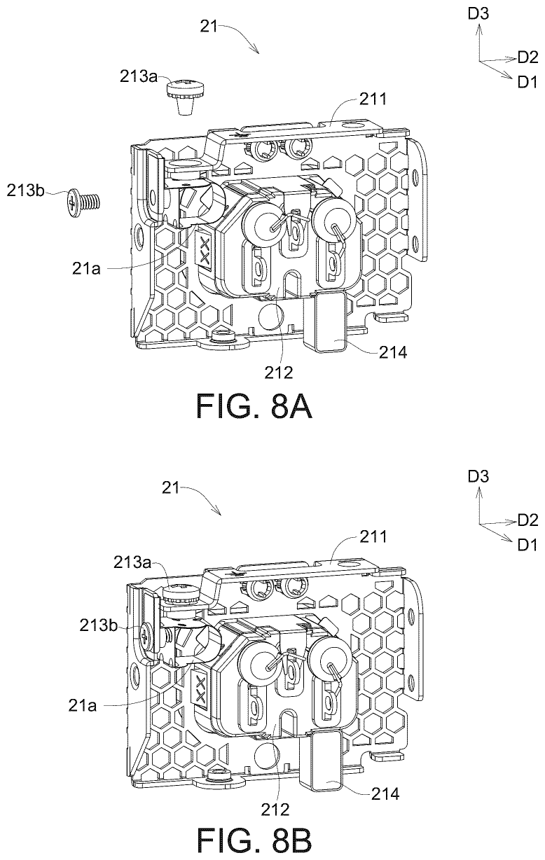

FIG. 5 is a schematic diagram of a socket device 2 or 3 according to a second embodiment and a third embodiment of the present invention. FIG. 6 is an exploded schematic diagram of a socket device 2 according to the second embodiment of the present invention. FIG. 7 is an exploded schematic diagram of a socket device 3 according to the third embodiment of the present invention. FIGS. 8A and 8B are schematic diagrams of a socket module 21 according to the second embodiment and the third embodiment of the present invention.

Please refer to FIG. 5, the socket device 2 or 3 includes a housing 20, a socket module 21, a fan 22, and a fixing member 23. The length of the housing 20 in the first direction D1 may be less than the length of the housing 10 in the first direction D1. The fan 22 and the fixing member 23 are similar to the fan 12 and the fixing member 13, respectively. Other identical or similar parts between the socket device 2 or 3 and the socket device 1 will not be described in detail.

As shown in FIGS. 6 and 7, the housing 20 may include a first housing member 20a and a second housing member 20b. The first housing member 20a and the second housing member 20b are assembled to form an accommodating space C21. The fan 22 is disposed within the accommodating space C21. The first housing member 20a and the second housing member 20b can respectively form a first opening P21 and a second opening P22 corresponding to the fan 22. The first opening P21 and the second opening P22 respectively expose a part of the fan 22.

The difference between the socket device 2 and 3 lies in the different airflow direction F of the fan 22, and other identical or similar parts will not be described in detail. As shown in FIG. 6, the airflow direction F of the fan 22 of the socket device 2 is directed towards the socket module 21 located at the first end E1, so that the airflow blows towards the socket module 21. As shown in FIG. 7, the airflow direction F of the fan 22 of the socket device 3 is directed towards the second end E2, i.e., in the opposite direction to the socket module 21. In other words, in the socket device 2 of the second embodiment and the socket device 3 of the third embodiment, the airflow directions F generated by the fan 22 are opposite.

As shown in FIGS. 8A and 8B, the socket module 21 includes a cover member 211, a socket member 212, an elastic member 21a, a first fastening member 213a, a second fastening member 213b, and a conductive member 214. The cover member 211, socket member 212, elastic member 21a, first fastening member 213a, and second fastening member 213b are respectively identical or similar to the cover member 111, socket member 112, elastic member 11a, first fastening member 113a, and second fastening member 113b. Other identical parts will not be described in detail. The conductive member 214 includes a conductive material, such as conductive foam. Compared to the socket module 11, since the socket module 21 further includes the conductive member 214, the problems of electromagnetic compatibility (EMC) and electromagnetic interference (EMI) can be better improved.

In summary, the present invention provides a socket module and a socket device including the same, which have improved electromagnetic compatibility and electromagnetic interference problems. The socket module includes a cover member, a socket member, an elastic member, a first fastening member, and a second fastening member. The socket member penetrates through the cover member, and the socket member includes a first pin, wherein the first pin serves as a ground wire. The elastic member is engaged in the cover member, is in electrical contact with the socket member, and is electrically connected to the first pin. The first fastening member and the second fastening member abut against and press the elastic member in different directions, and the elastic member is secured within the cover member by the first fastening member and the second fastening member, wherein the elastic member has a closed structure.

Compared to an elastic member with a non-closed structure, since the elastic member of the present invention has a closed structure and is squeezed by the first fastening member and the second fastening member, the elastic member can form good electrical contact with the socket member. Therefore, a reliable grounding effect can be provided for the socket member, thereby solving the problems of electromagnetic compatibility and electromagnetic interference of the socket device. Furthermore, the elastic member of the present invention itself has a small size and can be engaged in the cover member, conforming to the space limitations of the socket module and/or the socket device. The elastic member is not difficult to assemble, can maintain the quality yield of mass production, and is suitable for large-scale production. In addition, the elastic member of the present invention can meet the structural strength testing requirements, and there is no concern about detachment.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A socket module, comprising:
a cover member;
a socket member, passing through the cover member, wherein the socket member comprises a first pin, and the first pin serves as a ground wire;
an elastic member, engaged in the cover member, in electrical contact with the socket member, and electrically connected to the first pin; and
a first fastening member and a second fastening member, abutting against and pressing the elastic member along different directions, wherein the elastic member is secured within the cover member by the first fastening member and the second fastening member, and wherein the elastic member is a closed structure.

2. The socket module according to claim 1, wherein the socket member further comprises a base, a conductive ring, a second pin, and a third pin, wherein the first pin, the second pin, and the third pin pass through the base, wherein the second pin serves as a neutral wire, the third pin serves as a live wire, and the conductive ring surrounds the base and is electrically connected to the first pin.

3. The socket module according to claim 1, wherein the cover member comprises a first recess and a second recess, wherein the first recess and the second recess are respectively located on adjacent sides of the cover member, and the first recess and the second recess respectively have a first through hole and a second through hole, wherein the first through hole and the second through hole respectively expose a part of the elastic member.

4. The socket module according to claim 3, wherein the elastic member comprises a body portion and an extension portion, wherein the extension portion is connected to the body portion, wherein the body portion has the closed structure, wherein the extension portion comprises a first component, a second component, and a third component, the second component is connected between the first component and the third component, the first component is connected to the body portion, the second component and the third component partially protrude from the first component, and the third component has a fixing hole.

5. The socket module according to claim 4, wherein the second recess of the cover member is clamped between the first component, the second component, and the third component, and the fixing hole corresponds to the second through hole.

6. The socket module according to claim 5, wherein the first through hole exposes a portion of a top surface of the body portion, the second through hole exposes a portion of a side surface of the body portion, the first fastening member passes through the first through hole to contact and press against the top surface, and the second fastening member passes through the fixing hole and the second through hole to contact and press the side surface of the body portion.

7. The socket module according to claim 6, wherein two end regions of the body portion overlap each other to form an overlapping portion, wherein the overlapping portion comprises an upper layer and a lower layer formed by the body portion.

8. The socket module according to claim 7, wherein the body portion further comprises a engaging portion, wherein the upper layer and the lower layer are fixed to each other by the engaging portion, the engaging portion comprises a first engaging hole, a second engaging hole, and a fixing structure adjacent to the second engaging hole, wherein the first engaging hole is formed in the upper layer, the second engaging hole and the fixing structure are formed in the lower layer, the first engaging hole and the second engaging hole overlap each other, and the fixing structure passes through the first engaging hole and folds outward.

9. The socket module according to claim 7, wherein the elastic member further comprises a first angle and a second angle, wherein the first angle is formed between the top surface and an inner side surface of the first component adjacent to the top surface, the second angle is formed between a first internal surface and a second internal surface of the body portion adjacent to each other, and
the elastic member further comprises a first reinforcing rib and a second reinforcing rib, wherein the first reinforcing rib corresponds to the first angle, the second reinforcing rib corresponds to the second angle, wherein the first reinforcing rib is formed by a part of the body portion and a part of the first component protruding in a direction away from the third component, and the second reinforcing rib is formed by the body portion protruding in the direction away from the third component.

10. A socket device, comprising:
a housing, comprising a first end and a second end opposite to each other along a long axis;
the socket module according to claim 1, disposed at the first end; and
a fan, disposed between the first end and the second end.

11. The socket device according to claim 10, further comprising a fixing member, wherein the fixing member is connected to the socket module.

12. The socket device according to claim 10, wherein an airflow direction of the fan is towards the first end.

13. The socket device according to claim 10, wherein an airflow direction of the fan is towards the second end.
